(19) United States
(12) Patent Application Publication
(10) Pub. No.: US 2025/0341444 A1
(43) Pub. Date: Nov. 6, 2025

(54) DETERIORATION ESTIMATION METHOD, LASER DEVICE, AND ELECTRONIC DEVICE MANUFACTURING METHOD

(71) Applicant: Gigaphoton Inc., Tochigi (JP)

(72) Inventors: Yusuke SAITO, Oyama-shi (JP); Shinichi MATSUMOTO, Oyama-shi (JP); Masato MORIYA, Oyama-shi (JP); Takamitsu KOMAKI, Oyama-shi (JP)

(73) Assignee: Gigaphoton Inc., Tochigi (JP)

(21) Appl. No.: 19/264,346

(22) Filed: Jul. 9, 2025

Related U.S. Application Data
(63) Continuation of application No. PCT/JP2023/003836, filed on Feb. 6, 2023.

(51) Int. Cl. G01M 11/02; G03F 7/20; H01S 3/00

(52) U.S. Cl. CPC G01M 11/02; G03F 7/20; H01S 3/0057

(57) ABSTRACT

A deterioration estimation method of an optical pulse stretcher configured to extend a pulse width of pulse laser light includes acquiring a first temporal waveform, at a first measurement timing, of the pulse laser light having the pulse width extended by the optical pulse stretcher; acquiring a second temporal waveform, at a second measurement timing after the first measurement timing, of the pulse laser light having the pulse width extended by the optical pulse stretcher; and estimating a degree of deterioration of the optical pulse stretcher based on the first temporal waveform and the second temporal waveform.

### CROSS-REFERENCE TO RELATED APPLICATIONS

The present application is a continuation application of International Application No. PCT/JP2023/003836, filed on Feb. 6, 2023, the entire contents of which are hereby incorporated by reference.

### BACKGROUND

### 1. Technical Field

The present disclosure relates to a deterioration estimation method, a laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: US Patent Application Publication No. 2004/0009620

Patent Document 2: US Patent Application Publication No. 2003/0227954

### SUMMARY

A deterioration estimation method, according to an aspect of the present disclosure, of an optical pulse stretcher configured to extend a pulse width of pulse laser light includes acquiring a first temporal waveform, at a first measurement timing, of the pulse laser light having the pulse width extended by the optical pulse stretcher; acquiring a second temporal waveform, at a second measurement timing after the first measurement timing, of the pulse laser light having the pulse width extended by the optical pulse stretcher; and estimating a degree of deterioration of the optical pulse stretcher based on the first temporal waveform and the second temporal waveform.

A laser device according to another aspect of the present disclosure includes an oscillator configured to output pulse laser light; an optical pulse stretcher configured to extend a pulse width of the pulse laser light; a pulse waveform measurement instrument configured to measure a first temporal waveform, at a first measurement timing, of the pulse laser light having the pulse width extended by the optical pulse stretcher, and measure a second temporal waveform, at a second measurement timing after the first measurement timing, of the pulse laser light having the pulse width extended by the optical pulse stretcher; and a processor configured to estimate a degree of deterioration of the optical pulse stretcher based on the first temporal waveform and the second temporal waveform.

An electronic device manufacturing method according to another aspect of the present disclosure includes generating laser light with a pulse width extended using a laser device, outputting the laser light to an exposure apparatus, and exposing a photosensitive substrate to the laser light in the exposure apparatus to manufacture an electronic device. Here, the laser device includes an oscillator configured to output pulse laser light; an optical pulse stretcher configured to extend the pulse width of the pulse laser light; a pulse waveform measurement instrument configured to measure a first temporal waveform, at a first measurement timing, of the pulse laser light having the pulse width extended by the optical pulse stretcher, and measure a second temporal waveform, at a second measurement timing after the first measurement timing, of the pulse laser light having the pulse width extended by the optical pulse stretcher; and a processor configured to estimate a degree of deterioration of the optical pulse stretcher based on the first temporal waveform and the second temporal waveform.

### BRIEF DESCRIPTION OF THE DRAWINGS

Embodiments of the present disclosure will be described below merely as examples with reference to the accompanying drawings.

FIG. 1 schematically shows the configuration of a laser device according to a comparative example.

FIG. 2 is an explanatory view of a measurement method of a transmittance of an optical pulse stretcher (OPS) of the laser device according to the comparative example.

FIG. 3 is an explanatory view for the measurement method of the transmittance of the OPS of the laser device according to the comparative example.

FIG. 4 schematically shows the configuration of the laser device according to a first embodiment.

FIG. 5 is a flowchart showing a procedure of a deterioration estimation method according to the first embodiment.

FIG. 6 is a graph showing a first temporal waveform and a second temporal waveform of pulse laser light having passed through the OPS.

FIG. 7 schematically shows the configuration of the laser device according to a modification of the first embodiment.

FIG. 8 is a flowchart showing a procedure of the deterioration estimation method according to a second embodiment.

FIG. 9 is a graph showing an example of a case in which the second temporal waveform is normalized so that the maximum value at a first peak of each of the first temporal waveform and the second temporal waveform becomes the same.

FIG. 10 is a graph showing an example of a case in which the second temporal waveform is normalized so that the maximum value at a second peak of each of the first temporal waveform and the second temporal waveform becomes the same.

FIG. 11 is a flowchart showing a procedure of the deterioration estimation method according to a third embodiment.

FIG. 12 schematically shows the configuration of the laser device according to a fourth embodiment.

FIG. 13 is a flowchart showing a procedure of the deterioration estimation method according to the fourth embodiment.

FIG. 14 is a graph showing an example of the first temporal waveform and the normalized second temporal waveform when a delay optical path length of a second OPS is twice a delay optical path length of a first OPS.

FIG. 15 is a graph showing an example of the first temporal waveform and the normalized second temporal waveform when the delay optical path length of the second OPS is three times the delay optical path length of the first OPS.

FIG. 16 schematically shows the configuration of the laser device according to a fifth embodiment.

FIG. 17 schematically shows the configuration of the laser device according to a sixth embodiment.

FIG. 18 schematically shows a configuration example of an exposure apparatus.

### DESCRIPTION OF EMBODIMENTS

### Contents

1. Overview of laser device according to comparative example
1.1 Configuration
1.2 Operation
1.3 Deterioration estimation method of OPS according to comparative example
1.4 Problem
   2. First embodiment
2.1 Configuration
2.2 Operation
2.3 Effect
2.4 Modification
   2.4.1 Configuration
   2.4.2 Operation
   2.4.3 Effect
      3. Second embodiment
3.1 Configuration
3.2 Operation
3.3 Effect
   4. Third embodiment
4.1 Configuration
4.2 Operation
4.3 Effect
   5. Fourth embodiment
5.1 Configuration
5.2 Operation
5.3 Effect
5.4 First modification
5.5 Second modification
   6. Fifth embodiment
6.1 Configuration
6.2 Operation
6.3 Effect
   7. Sixth embodiment
7.1 Configuration
7.2 Operation
7.3 Effect
   8. Other modification of laser device
   9. Electronic device manufacturing method

### 10. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overview of Laser Device According to Comparative Example

### 1.1 Configuration

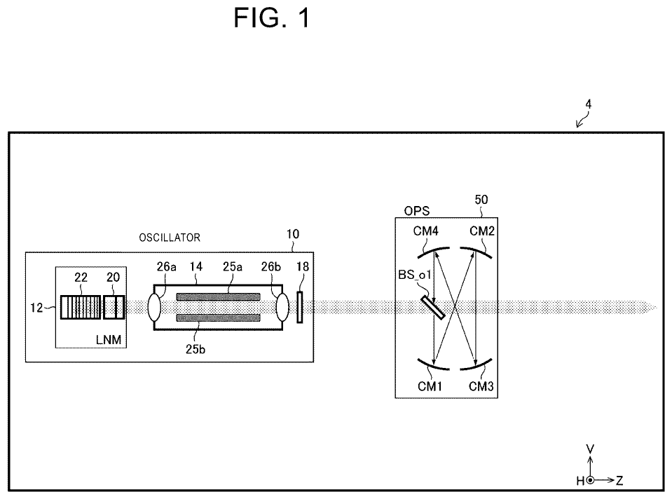

FIG. 1 schematically shows the configuration of a laser device 4 according to a comparative example. The comparative example of the present disclosure is an example recognized by the applicant as known only by the applicant, and is not a publicly known example admitted by the applicant. The laser device 4 includes an oscillator 10 and an optical pulse stretcher (OPS) 50.

The oscillator 10 includes a line narrowing module (LNM) 12, a chamber 14, and an output coupling mirror 18. The LNM 12 includes a prism beam expander 20 and a grating 22 for narrowing the spectral line width. The grating 22 is arranged in the Littrow arrangement so that the incident angle and the diffraction angle coincide with each other.

The output coupling mirror 18 is a partial reflection mirror and is arranged to configure an optical resonator together with the LNM 12. The reflectance of the output coupling mirror 18 may be between 20% and 30%.

The chamber 14 is arranged on the optical path of the optical resonator, and includes a pair of electrode 25a, 25b and two windows 26a, 26b through which laser light is transmitted. An excimer laser gas is introduced into the chamber 14. The excimer laser gas may include, for example, an Ar gas or a Kr gas as a rare gas, an Fe gas as a halogen gas, and an Ne gas as a buffer gas.

The OPS 50 includes a beam splitter BS_o1 and four concave mirrors CM1 to CM4 configuring a delay optical path. The beam splitter BS_o1 and the concave mirrors CM1 to CM4 are arranged so that the laser light reflected by the beam splitter BS_o1 is reflected by the four concave mirrors CM1 to CM4, and the beam is focused again on the beam splitter BS_o1. At least one of the concave mirrors CM1 to CM4 may include an actuator for changing a posture angle thereof.

### 1.2 Operation

A pulse high voltage is applied between the electrodes 25a, 25b in the chamber 14 at a predetermined repetition frequency from a power source (not shown) based on control of a control unit (not shown). When discharge occurs between the electrodes 25a, 25b, the laser gas is excited, and pulse laser light line-narrowed by the optical resonator configured by the output coupling mirror 18 and the LNM 12 is output from the output coupling mirror 18.

The pulse laser light output from the output coupling mirror 18 enters the OPS 50, and a part of the pulse laser light passes through the delay optical path in the OPS 50 a plurality of times, so that the pulse laser light is extended to a predetermined pulse width.

### 1.3 Deterioration Estimation Method of OPS According to Comparative Example

When the OPS 50 deteriorates, the oscillator load increases and the lifetime of the oscillator 10 is shortened, and specifications for the time width of the pulse laser light become unsatisfied. Therefore, a transmittance of the OPS 50 is measured at the time of periodic maintenance, and deterioration of the OPS 50 is estimated.

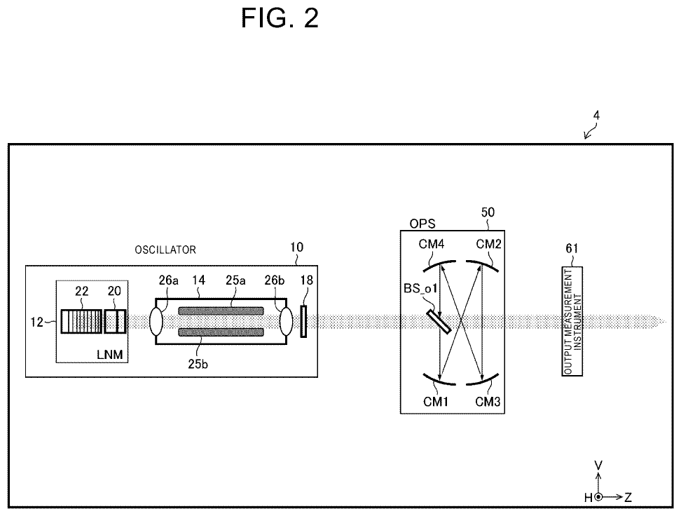

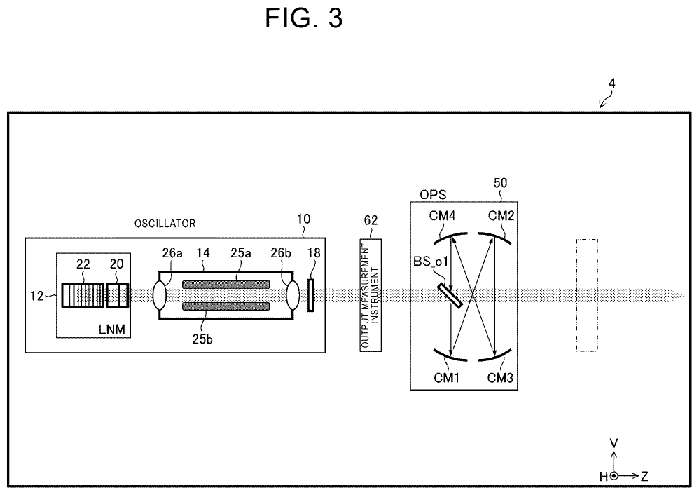

FIGS. 2 and 3 are explanatory views for a measurement method of the transmittance of the OPS 50. When measuring the transmittance of the OPS 50, first, as shown in FIG. 2, an output measurement instrument 61 is installed so that the output of the pulse laser light having passed through the OPS 50 can be measured. Then, the output of the pulse laser light having passed through the OPS 50 is measured by the output measurement instrument 61.

Next, as shown in FIG. 3, an output measurement instrument 62 is installed so that the output of the pulse laser light before passing through the OPS 50 can be measured. Then, the output of the pulse laser light before passing through the OPS 50 is measured by the output measurement instrument 62.

Thus, the transmittance of the OPS 50 is calculated based on the output of the pulse laser light before and after passing through the OPS 50. If the transmittance of the OPS 50 is equal to or less than a predetermined value, it is estimated that the OPS 50 has deteriorated, and the OPS 50 is to be replaced. For example, if the transmittance of the OPS 50 is 90% or less, it is estimated that the OPS 50 has deteriorated, and the OPS 50 is to be replaced.

### 1.4 Problem

In the method of estimating deterioration of the OPS 50 by measuring the transmittance of the OPS 50, the output of the laser light is required to be measured before and after passing through the OPS 50. Therefore, as shown in FIGS. 2 and 3, two installation locations for installing the output measurement instruments 61, 62 are required.

### 2. First Embodiment

### 2.1 Configuration

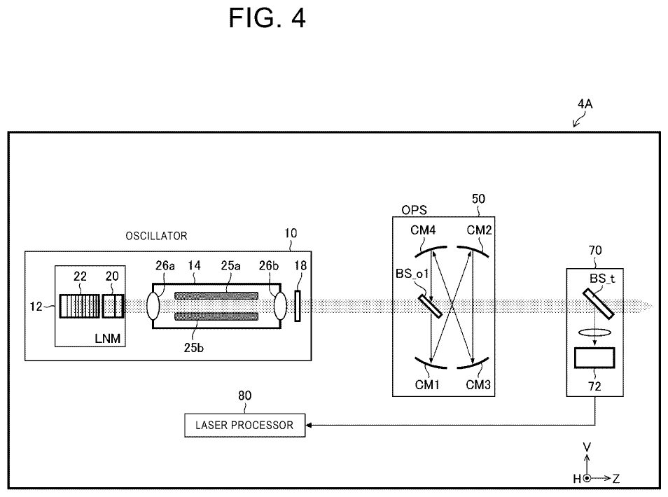

FIG. 4 schematically shows the configuration of a laser device 4A according to a first embodiment. The laser device 4A shown in FIG. 4 will be described in terms of differences from the configuration shown in FIG. 1.

The laser device 4A according to the first embodiment is different from the laser device 4 of the comparative example in that a pulse waveform measurement instrument 70 for measuring a temporal waveform of the pulse laser light having passed through the OPS 50 is installed to estimate deterioration of the OPS 50. The pulse waveform measurement instrument 70 may be permanently installed or may be installed only at the time of maintenance.

The pulse waveform measurement instrument 70 includes a beam splitter BS_t and a laser pulse detector 72. A part of the pulse laser light entering the pulse waveform measurement instrument 70 is reflected by the beam splitter BS t and enters the laser pulse detector 72. The pulse laser light transmitted through the beam splitter BS_t is output from the laser device 4A. The laser pulse detector 72 measures the temporal waveform of the pulse laser light with temporal resolution of nanosecond (ns) order. The laser pulse detector 72 may be, for example, a biplanar photoelectric tube. The temporal waveform of the pulse laser light is a pulse waveform indicating a temporal change in the light intensity of the pulse laser light.

Further, the laser device 4A includes a laser processor 80 that performs a deterioration estimation process of the OPS 50 based on information obtained from the pulse waveform measurement instrument 70.

The laser processor 80 is a processing device including a storage device in which a control program is stored and a central processing unit (CPU) that executes the control program. The laser processor 80 is specifically configured or programmed to perform various processes included in the present disclosure. The laser processor 80 may include an integrated circuit such as a field programmable gate array (FPGA) or an application specific integrated circuit (ASIC). Other configurations may be similar to those of the laser device 4 shown in FIG. 1. The laser processor 80 is an example of the “processor” in the present disclosure.

### 2.2 Operation

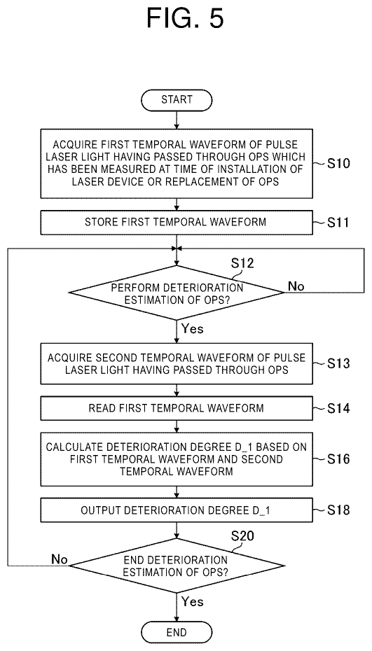

FIG. 5 is a flowchart showing a procedure of a deterioration estimation method according to the first embodiment. In step S10, the laser processor 80 acquires a first temporal waveform of the pulse laser light having passed through the OPS 50, which has been measured by the pulse waveform measurement instrument 70 at the time of installation of the laser device 4A or replacement of the OPS 50. The first temporal waveform is the temporal waveform measured in an initial state at the start of using the OPS 50. The timing of measuring the temporal waveform of the pulse laser light by the pulse waveform measurement instrument 70 at the time of installation of the laser device 4A or replacement of the OPS 50 is an example of the “first measurement timing” in the present disclosure.

In step S11, the laser processor 80 stores the first temporal waveform received from the pulse waveform measurement instrument 70 in the storage device.

In step S12, the laser processor 80 determines whether or not to perform deterioration estimation of the OPS 50. There may be various forms of conditions for performing deterioration estimation. For example, it may be defined that deterioration estimation is performed when the pulse high voltage applied between the electrodes 25a, 25b in the chamber 14 is increased by 10% or when the gas pressure in the chamber 14 is increased by 10% for obtaining a target pulse energy. Further, the laser processor 80 may accept an instruction to perform deterioration estimation from a user interface as necessary, such as at the time of periodic maintenance, or may be configured to automatically perform deterioration estimation periodically or irregularly according to a predetermined program.

The laser processor 80 repeats step S12 when the determination result of step S12 is No.

When the determination result of step S12 is Yes, the laser processor 80 proceeds to step S13.

In step S13, the laser processor 80 acquires a second temporal waveform of the pulse laser light having passed through the OPS 50, which is measured by the pulse waveform measurement instrument 70 when performing deterioration estimation of the OPS 50 such as at the time of maintenance. The timing of measuring the temporal waveform of the pulse laser light by the pulse waveform measurement instrument 70, which is the timing when performing deterioration estimation such as at the time of maintenance, is an example of the “second measurement timing” in the present disclosure.

In step S14, the laser processor 80 reads the first temporal waveform from the storage device. Then, in step S16, the laser processor 80 calculates a deterioration degree D_1 indicating the degree of deterioration of the OPS 50 based on the first temporal waveform and the second temporal waveform.

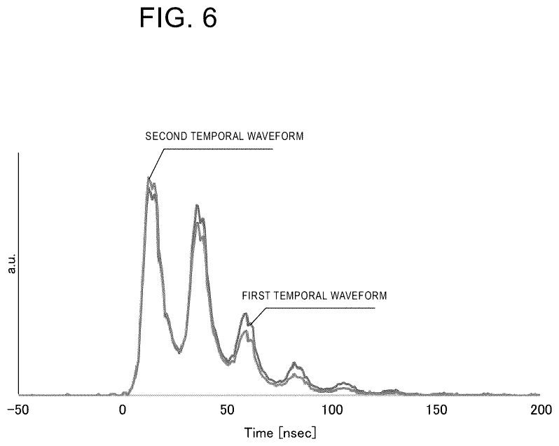

For example, when the first temporal waveform and the second temporal waveform are as shown in FIG. 6, the laser processor 80 calculates the deterioration degree D_1 in the following manner. That is, the laser processor 80 calculates a ratio R_12S of a maximum value P_1S at a first peak and a maximum value P_2S at a second peak of the first temporal waveform by Expression (1) below.

$$R\_ 12 S = P\_ 2 S / P\_ 1 S \qquad ( 1 )$$

Here, the first peak refers to a peak that appears at the first among the plurality of peaks included in the temporal waveform of the pulse laser light. The second peak refers to a peak that appears at the second among the plurality of peaks included in the temporal waveform. Similarly, for the third peak and later, a peak that appears at the k-th is referred to as the k-th peak.

Further the laser processor 80 calculates a ratio R_12E of a maximum value P_1E at a first peak and a maximum value P_2E at a second peak of the second temporal waveform by Expression (2) below.

$$R\_ 12 E = P\_ 2 E / P\_ 1 E \qquad ( 2 )$$

Then, the laser processor 80 calculates the deterioration degree D_1 by Expression (3) below.

$$D\_ 1 = R\_ 12 S - R\_ 12 E \qquad ( 3 )$$

In step S18, the laser processor 80 outputs the calculation result of the deterioration degree D_1 to a display device (not shown) or the like of the laser device 4A.

When the deterioration degree D_1 is equal to or more than a first setting value PV_1, the laser processor 80 estimates that the OPS 50 has deteriorated, and may output information such as a message or an alert prompting a user to replace the OPS 50 to the display device or the like. The first setting value PV_1 is, for example, 10%.

The user such as a field service engineer checks the calculation result of the deterioration degree D_1 displayed on the display device or the like, and replaces the OPS 50 when the deterioration degree D_1 is equal to or more than the first setting value PV_1.

Further, for example, when the deterioration degree D_1 is less than the first setting value PV_1, the laser processor 80 may further calculate the number of used pulses OPS1_dpls of the OPS 50 with which the deterioration degree D_1 becomes the first setting value PV_1. When the number of used pulses of the OPS 50 at the time of measurement of the second temporal waveform is OPS1_pls, OPS1_dpls may be calculated by Expression (4) below.

$$OPS1\_dpls = PV\_ 1 / ( D\_ 1 / OPS1\_pls ) \qquad ( 4 )$$

The replacement timing of the OPS 50 in the future can be estimated (predicted) from the value of OPS1_dpls calculated by Expression (4). The calculation result of OPS1_dpls may be output to the display device or the like together with the calculation result of the deterioration degree D_1.

Next, in step S20, the laser processor 80 determines whether or not to end the deterioration estimation process of the OPS 50. When the determination result of step S20 is No, the laser processor 80 returns to step S12.

When the determination result of step S20 is Yes, the laser processor 80 ends the flowchart of FIG. 5.

### 2.3 Effect

According to the deterioration estimation method of the first embodiment, the following effects can be obtained.
[1] By using the pulse waveform measurement instrument 70 instead of the output measurement instruments 61, 62 of FIGS. 2 and 3, deterioration of the OPS 50 can be estimated from the measurement result of only the pulse laser light having passed through the OPS 50.
[2] The installation position of the pulse waveform measurement instrument 70 is one position, so that the measurement time can be shortened.
[3] Even if the replacement is not performed immediately, the replacement timing of the OPS 50 in the future can be estimated from the deterioration degree D_1 of the OPS 50.

### 2.4 Modification

### 2.4.1 Configuration

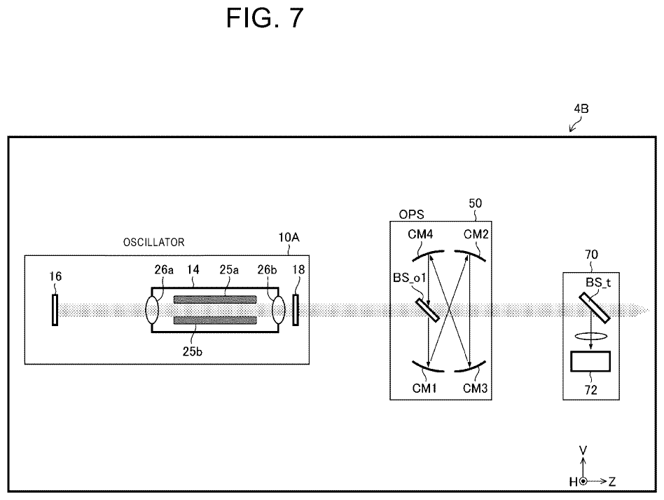

FIG. 7 schematically shows the configuration of a laser device 4B according to a modification of the first embodiment. The laser device 4B will be described in terms of differences from the configuration shown in FIG. 5. The laser device 4B includes an oscillator 10A including a rear mirror 16 instead of the oscillator 10 including the LNM 12 shown in FIG. 5. The rear mirror 16 may be a total reflection mirror and is arranged to configure an optical resonator together with the output coupling mirror 18. Other configurations are similar to those of the laser device 4A shown in FIG. 5.

### 2.4.2 Operation

When discharge occurs between the electrodes 25a, 25b in the chamber 14, the laser gas is excited, and pulse laser light having an ultraviolet wavelength of 150 to 380 nm is output from the output coupling mirror 18 due to the optical resonator configured by the output coupling mirror 18 and the rear mirror 16. Other operation is similar to the operation of the laser device 4B of the first embodiment.

### 2.4.3 Effect

Effects of the deterioration estimation method of the laser device 4B according to the modification of the first embodiment are similar to those of the first embodiment.

### 3. Second embodiment

### 3.1 Configuration

The configuration of the laser device according to a second embodiment may be similar to the configuration of the laser device 4A shown in FIG. 4 or the laser device 4B shown in FIG. 7.

### 3.2 Operation

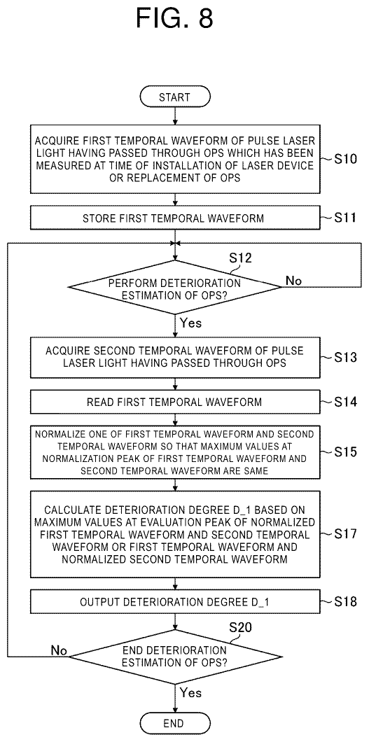

FIG. 8 is a flowchart showing a procedure of the deterioration estimation method according to the second embodiment. FIG. 8 will be described in terms of differences from the flowchart of FIG. 5. The flowchart shown in FIG. 8 includes step S15 and step S17 instead of step S16 of FIG. 5.

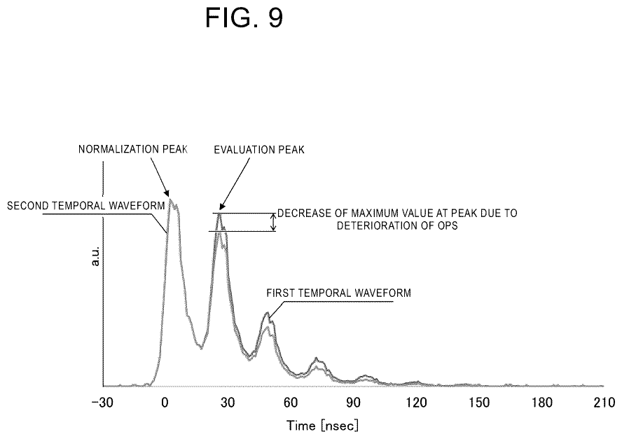

That is, after step S14, in step S15, the laser processor 80 normalizes one of the first temporal waveform and the second temporal waveform so that the maximum values at any one of the peaks (hereinafter, referred to as a normalization peak) of the both waveforms are the same when the positions of the respective peaks of the first temporal waveform and the second temporal waveform are displayed to be overlapped to each other. For example, as shown in FIG. 9, the normalization peak is the first peak, and the second temporal waveform is normalized based on the maximum values at the first peak of the first temporal waveform and the second temporal waveform.

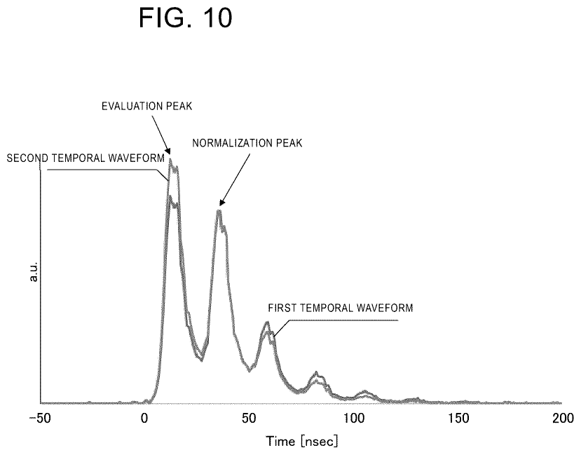

Alternatively, for example, as shown in FIG. 10, the normalization peak is the second peak, and the second temporal waveform is normalized based on the maximum values at the second peak of the first temporal waveform and the second temporal waveform. Here, the present invention is not limited to the examples shown in FIGS. 9 and 10, and the first temporal waveform may be normalized.

Then, in step S17, the laser processor 80 calculates the deterioration degree D_1 indicating the degree of deterioration of the OPS 50 from any one of the peaks other than the normalization peak. The peak used for the calculation of the deterioration degree D_1 is referred to as an evaluation peak. In FIG. 9, the evaluation peak is the second peak, and in FIG. 10, the evaluation peak is the first peak.

For example, when the maximum value at the evaluation peak of the normalized first temporal waveform is P_AS1 and the maximum value at the evaluation peak of the second temporal waveform is P_AE1, or when the maximum value at the evaluation peak of the first temporal waveform is P_AS1 and the maximum value at the evaluation peak of the normalized second temporal waveform is P_AE1, the deterioration degree D_1 is calculated by Expression (5) below.

$$D\_ 1 = \vert 1 - ( P\_AE1 / P\_AS1 ) \vert \qquad ( 5 )$$

After step S17, the laser processor 80 proceeds to step S18. Other operation may be similar to that in FIG. 5.

Here, deterioration estimation of the OPS 50 can be performed even when the normalization peak is the first peak and the evaluation peak is the third peak or later. However, it is desirable that the second peak is the evaluation peak. This is because, at the third peak and later, the maximum value of the peaks becomes small, and influence of noise may become large.

Further, the normalization peak may be the third peak or later. In this case as well, the deterioration degree D_1 can be calculated by Expression (5).

### 3.3 Effect

Effects of the second embodiment are similar to those of the first embodiment.

### 4. Third embodiment

### 4.1 Configuration

The configuration of the laser device according to a third embodiment may be similar to the configuration of the laser device 4A shown in FIG. 4 or the laser device 4B shown in FIG. 7.

### 4.2 Operation

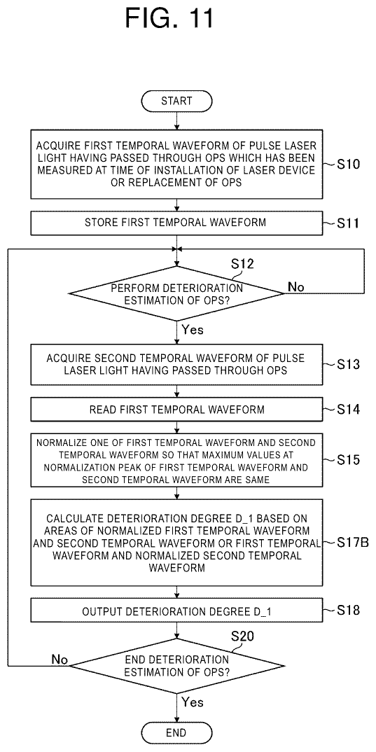

FIG. 11 is a flowchart showing a procedure of the deterioration estimation method according to the third embodiment. FIG. 11 will be described in terms of differences from the flowchart of FIG. 8. The flowchart shown in FIG. 11 includes step S17B instead of step S17 of FIG. 8.

That is, after step S15, in step S17B, the laser processor 80 calculates the deterioration degree D_1 indicating the degree of deterioration of the OPS 50 based on the area of each of the normalized first temporal waveform and the second temporal waveform or the area of each of the first temporal waveform and the normalized second temporal waveform. Here, the area represents a value of a definite integral of each of the normalized first temporal waveform and the second temporal waveform, or a value of a definite integral of each of the first temporal waveform and the normalized second temporal waveform.

Here, for example, when the first temporal waveform is normalized, let the area of the normalized first temporal waveform be S_2S and the area of the second temporal waveform be S_2E. Alternatively, when the second temporal waveform is normalized, let the area of the first temporal waveform be S_2S, and the area of the normalized second temporal waveform be S_2E. Then, the laser processor 80 calculates the deterioration degree D_1 by Expression (6) below.

$$D\_ 1 = 1 - S\_ 2 E / S\_ 2 S \qquad ( 6 )$$

After step S17B, the laser processor 80 proceeds to step S18. Other operation may be similar to that in FIG. 5.

### 4.3 Effect

Effects of the third embodiment are similar to those of the first embodiment.

### 5. Fourth embodiment

### 5.1 Configuration

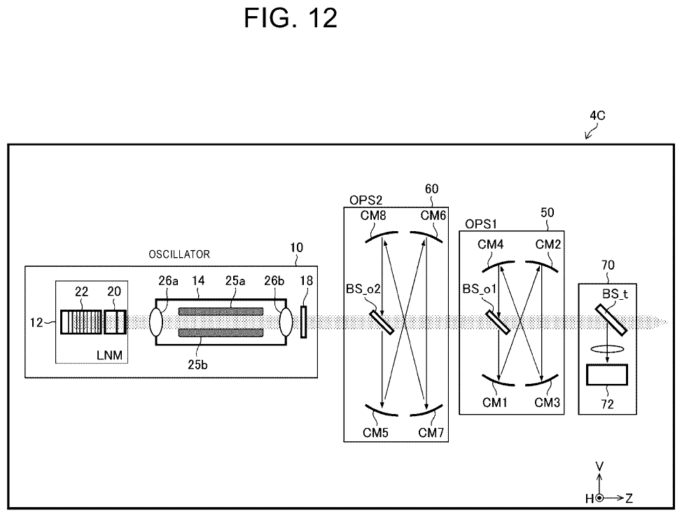

FIG. 12 schematically shows the configuration of a laser device 4C according to a fourth embodiment. The laser device 4C will be described in terms of differences from the configuration of the laser device 4A according to the first embodiment shown in FIG. 4.

The laser device 4C according to the fourth embodiment is different from the laser device 4A according to the first embodiment in that an OPS 60 is arranged between the oscillator 10 and the OPS 50.

The OPS 60 includes a beam splitter BS_o2 and four concave mirrors CM5 to CM8 configuring a delay optical path. The beam splitter BS_o2 and the concave mirrors CM5 to CM8 are arranged so that the laser light reflected by the beam splitter BS_o2 is reflected by the four concave mirrors CM5 to CM8, and the beam is focused again on the beam splitter BS_o2. At least one of the concave mirrors CM5 to CM8 may include an actuator for changing a posture angle thereof.

A delay optical path length of the OPS 60 is longer than a delay path length of the OPS 50. The magnification of the delay optical path length of the OPS 60 with respect to the delay optical path length of the OPS 50 is an integer of 2 or more, and this magnification is defined as M. Other configurations are similar to those of the laser device 4A according to the first embodiment.

The OPS 50 is an example of the “first optical pulse stretcher” in the present disclosure, and the OPS 60 is an example of the “second optical pulse stretcher” in the present disclosure. In the drawings such as FIG. 12, the notation “OPS1” represents the OPS 50 and the notation “OPS2” represents the OPS 60. The beam splitter BS_o1 of the OPS 50 is an example of the “first beam splitter” in the present disclosure, and the delay optical path configured by the concave mirrors CM1 to CM4 is an example of the “first delay optical path” in the present disclosure. The concave mirrors CM1 to CM4 are an example of the “plurality of mirrors configuring the first delay optical path” in the present disclosure. The beam splitter BS_o2 of the OPS 60 is an example of the “second beam splitter” in the present disclosure, and the delay optical path configured by the concave mirrors CM5 to CM8 is an example of the “second delay optical path” in the present disclosure. The concave mirrors CM5 to CM8 are an example of the “plurality of mirrors configuring the second delay optical path” in the present disclosure.

### 5.2 Operation

Operation of the device other than the OPS 60 is similar to that of the first embodiment. The pulse laser light output from the output coupling mirror 18 enters the OPS 60, and a part of the pulse laser light passes through the delay optical path in the OPS 60 a plurality of times so that the pulse laser light is extended to a predetermined pulse width. The pulse laser light having passed through the OPS 60 enters the OPS 50.

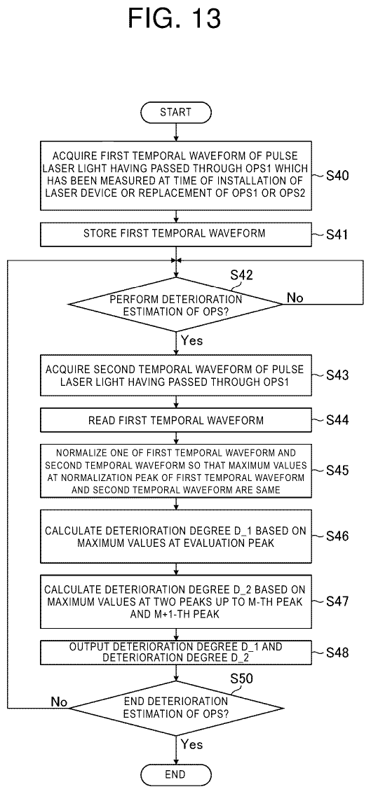

FIG. 13 is a flowchart showing a procedure of the deterioration estimation method according to the fourth embodiment. In step S40, the laser processor 80 acquires the first temporal waveform of the pulse laser light having passed through the OPS 50, which has been measured by the pulse waveform measurement instrument 70 at the time of installation of the laser device 4C or replacement of the OPS 50 or the OPS 60.

In step S41, the laser processor 80 stores the first temporal waveform received from the pulse waveform measurement instrument 70 in the storage device.

In step S42, the laser processor 80 determines whether or not to perform deterioration estimation for the entire OPS including the OPS 50 and the OPS 60. The laser processor 80 repeats step S42 when the determination result of step S42 is No.

When the determination result of step S42 is Yes, the laser processor 80 proceeds to step S43.

In step S43, the laser processor 80 acquires the second temporal waveform of the pulse laser light having passed through the OPS 50, which is measured by the pulse waveform measurement instrument 70 when performing deterioration estimation of the OPS 50 and the OPS 60 such as at the time of maintenance.

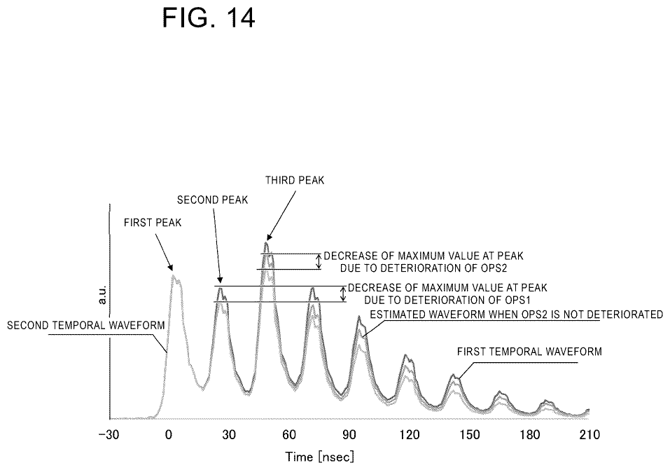

In step S44, the laser processor 80 reads the first temporal waveform from the storage device. Here, since the second peak of each of the first temporal waveform and the second temporal waveform includes only the circulation light of the OPS 50 having the short delay optical path length, the maximum value of the second peak decreases only due to deterioration of the OPS 50 having the short delay optical path length (see FIG. 14). Further, since the third peak and later include circulation light of the OPS 50 and circulation light of the OPS 60, the maximum values of the third peak and later decrease due to deterioration of the OPS 50 and the OPS 60.

In step S45, the laser processor 80 selects the normalization peak from the first to M-th peaks, and normalizes one of the first temporal waveform and the second temporal waveform so that the maximum values at the normalization peak of the both waveforms are the same.

For example, FIG. 14 shows an example of the first temporal waveform and the normalized second temporal waveform when the delay optical path length of the OPS 60 is twice the delay optical path length of the OPS 50. In FIG. 14, the normalization peak is the first peak, and an example of a waveform after the second temporal waveform is normalized based on the maximum values at the first peak of the first temporal waveform and the second temporal waveform is shown. Here, instead of normalizing the second temporal waveform, the first temporal waveform may be normalized.

In step S46, the laser processor 80 calculates the deterioration degree D_1 indicating the degree of deterioration of the OPS 50 based on the maximum value of the evaluation peak of each of the normalized first temporal waveform and the second temporal waveform, or the maximum value of the evaluation peak of each of the first temporal waveform and the normalized second temporal waveform. Here, it is preferable that the evaluation peak is selected from the first to M-th peaks as well. In the case of FIG. 14, since the normalization peak is the first peak, the evaluation peak is the second peak. The deterioration degree D_1 is calculated by Expression (5).

Next, in step S47, the laser processor 80 calculates a deterioration degree D_2 indicating the degree of deterioration of the OPS 60 based on the maximum values at the respective peaks of any two peaks from the first to M-th peak and the M+1-th peak. When the delay optical path length of the OPS 60 shown in FIG. 14 is twice the delay optical path length of the OPS 50, the deterioration degree D_2 can be calculated from the maximum values at the respective peaks of the first peak, the second peak, and the third peak.

The calculation expressions of the deterioration degree D_1 and the deterioration degree D_2 when the delay optical path length of the OPS 60 is twice the delay optical path length of the OPS 50 are shown below.

Let P_1S, P_2S, and P_3S be the maximum values at the first peak, the second peak, and the third peak of the first temporal waveform or the normalized first temporal waveform, respectively, and P_1E, P_2E, and P_3E be the maximum values at the first peak, the second peak, and the third peak of the second temporal waveform or the normalized second temporal waveform, respectively. Since the first peak is normalized, P_1S=P_1E.

Further, let the transmittance of the beam splitter BS_o1 be T_BSo1. The transmittance is not limited to a value obtained by actually measuring, and may be a designed value. Light transmitted through the beam splitter BS_o2 and circulated through the delay optical path of the OPS 50 twice and light circulated through the delay optical path of the OPS 60 once and transmitted through the beam splitter BS_o1 are combined in the third peak of the temporal waveform measured by the pulse waveform measurement instrument 70.

Let, in the third peak of the first temporal waveform or the normalized first temporal waveform, the maximum value of the light transmitted through the beam splitter BS_o2 and circulated through the delay optical path of the OPS 50 twice be P_3S1 and the maximum value of the light circulated through the delay optical path of the OPS 60 once and transmitted through the beam splitter BS_o1 be P_3S2, and in the third peak of the second temporal waveform or the normalized second temporal waveform, the maximum value of the light transmitted through the beam splitter BS_o2 and circulated through the delay optical path of the OPS 50 twice be P_3E1 and the maximum value of the light circulated through the delay optical path of the OPS 60 once and transmitted through the beam splitter BS_o1 be P_3S2. In this case, the third peak satisfies the relationship of Expressions (7) and (8) below.

$$P\_ 3 S = P\_ 3 S 1 + P\_ 3 S 2 \qquad ( 7 )$$

$$P\_ 3 E = P\_ 3 E 1 + P\_ 3 E 2 \qquad ( 8 )$$

The deterioration degree D_1 indicating the degree of deterioration of the OPS 50 is calculated by Expression (1).

The laser processor 80 calculates P_3S1 by Expression (9) below.

$$P\_ 3 S 1 = P\_ 2 S \times P\_ 2 S \times T\_BSol \times T\_BSol / P\_ 1 S / ( 1 - T\_BSol ) / ( 1 - T\_BSol ) \qquad ( 9 )$$

The laser processor 80 calculates P_3SE1 by Expression (10) below.

$$P\_ 3 E 1 = ( 1 - D\_ 1 ) \times ( 1 - D\_ 1 ) \times P\_ 3 S 1 \qquad ( 10 )$$

Then, the deterioration degree D_2 indicating the degree of deterioration of the OPS 60 is calculated by Expression (11) below.

$$D\_ 2 = 1 - ( P\_ 3 E - P\_ 3 E 1 ) / ( P\_ 3 S - P\_ 3 S 1 ) \qquad ( 11 )$$

In step S48, the laser processor 80 outputs the calculation results of the deterioration degree D_1 and the deterioration degree D_2 to the display device (not shown) or the like of the laser device 4. Then, when the deterioration degree D_1 is equal to or more than the first setting value PV_1, it is estimated that the OPS 50 has deteriorated, and the OPS 50 is to be replaced. The first setting value PV_1 is for example, 10%.

When the deterioration degree D_2 is equal to or more than a second setting value PV_2, the laser processor 80 estimates that the OPS 60 has deteriorated, and may output information such as a message or an alert prompting the user to replace the OPS 60 to the display device or the like. The second setting value PV_2 is, for example, 10%.

The user such as a field service engineer checks the calculation result of the deterioration degree D_2 displayed on the display device or the like, and replaces the OPS 60 when the deterioration degree D_2 is equal to or more than the second setting value PV_2.

Further, the laser processor 80 may calculate the number of used pulses OPS1_dpls of the OPS 50 with which the deterioration degree D_1 becomes the first setting value PV_1 by Expression (4). Further, when the number of used pulses of the OPS 50 at the time of measuring the second temporal waveform is OPS2_pls, the laser processor 80 may calculate the number of used pulses OPS2_dpls of the OPS 60 with which the deterioration degree D_2 becomes the second setting value PV_2 by Expression (12) below.

$$OPS2\_dpls = PV\_ 2 / ( D\_ 2 / OPS2\_pls ) \qquad ( 12 )$$

The replacement timing of the OPS 60 in the future can be estimated (predicted) from the value of OPS2_dpls calculated by Expression (12). The calculation results of OPS1_dpls and OPS2_dpls may be output to the display device or the like together with the calculation results of the deterioration degree D_1 and the deterioration degree D_2.

### 5.3 Effect

Effects of the fourth embodiment are similar to those of the first embodiment. Even when two optical pulse stretchers 50, 60 are arranged as shown in FIG. 12, the degree of deterioration of each OPS can be estimated.

### 5.4 First Modification

In the fourth embodiment, a case in which the delay optical path length of the OPS 60 is twice the delay optical path length of the OPS 50 has been described. However, even in cases of the magnification being other than twice, a peak position where the maximum value at the peak decreases due to deterioration of the OPS 50 and the OPS 60 can be known, and the degree of deterioration of each OPS can be estimated in a similar manner as described above.

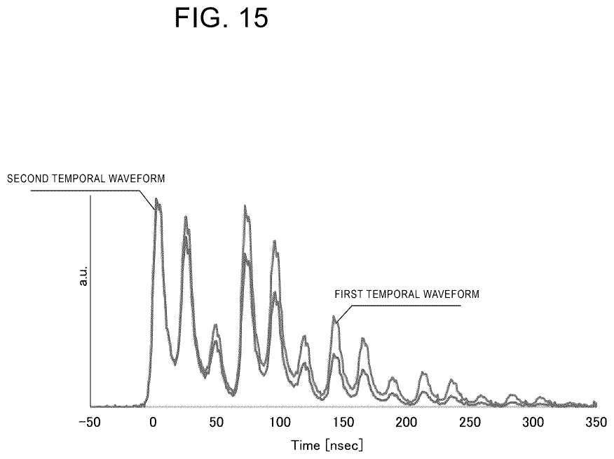

FIG. 15 shows an example of the first temporal waveform and the normalized second temporal waveform when the delay optical path length of the OPS 60 is three times the delay optical path length of the OPS 50. When M=3, the normalized peak is selected from the first to third peaks, and the evaluation peak is also selected from the first to third peaks. The deterioration degree D_2 is calculated by the maximum values at the respective peaks of any two peaks from the first to third peaks and the maximum value of the fourth peak.

### 5.5 Second Modification

Further, in the fourth embodiment, the calculation method of the deterioration degree D_1 and the deterioration degree D_2 when the OPS 60 is arranged between the oscillator 10 and the OPS 50 has been described. However, the arrangement relationship between the OPS 50 and the OPS 60 can be interchanged. That is, even in the configuration in which the OPS 50 is arranged between the oscillator 10 and the OPS 60, the deterioration degree D_1 of the OPS 50 can be calculated by Expression (5) and the deterioration degree D_2 of the OPS 60 can be calculated by Expression (11).

### 6. Fifth Embodiment

### 6.1 Configuration

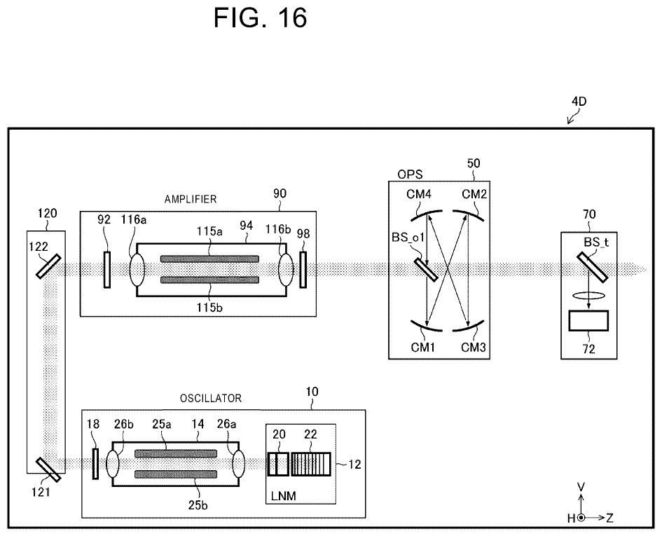

FIG. 16 schematically shows the configuration of a laser device 4D according to a fifth embodiment. The configuration of the laser device 4D will be described in terms of differences from the configuration of the laser device 4A according to the first embodiment shown in FIG. 4. The laser device 4D is different from the laser device 4A according to the first embodiment in that an amplifier 90 is arranged between the oscillator 10 and the OPS 50 and a beam steering unit 120 is arranged between the oscillator 10 and the amplifier 90. Other configurations may be similar to those of the laser device 4A.

The amplifier 90 includes a rear mirror 92, a chamber 94, and an output coupling mirror 98. The rear mirror 92 and the output coupling mirror 98 configure a Fabry-Perot optical resonator, and the chamber 94 is arranged on the optical path of the optical resonator.

The rear mirror 92 is a partial reflection mirror having a reflectance of 50% to 90%. The output coupling mirror 98 is a partial reflection mirror having a reflectance of 10% to 30%.

The chamber 94 includes a pair of electrodes 115a, 115b and two windows 116a, 116b through which the pulse laser light is transmitted. An excimer laser gas is introduced into the chamber 94. The excimer laser gas includes a rare gas, a halogen gas, and a buffer gas. The rare gas may be an Ar gas or a Kr gas. The halogen gas may be an F₂ gas. The buffer gas may be an Ne gas.

The beam steering unit 120 includes a high reflection mirror 121 and a high reflection mirror 122, and is arranged such that the pulse laser light output from the oscillator 10 enters the amplifier 90.

Here, not limited to the configuration including a Fabry-Perot resonator, the amplifier 90 may have configuration including a ring resonator. Alternatively, a single-pass amplifier or a multipass amplifier without an optical resonator may be included instead of the amplifier 90. For example, the multipass amplifier may be a three-pass amplifier that performs amplification by causing the seed light to pass through the discharge space three times as being reflected by cylindrical mirrors.

### 6.2 Operation

The pulse laser light having an ultraviolet wavelength output from the oscillator 10 is caused to be incident on the rear mirror 92 of the amplifier 90 as seed light by the beam steering unit 120.

At a timing when the seed light having transmitted through the rear mirror 92 enters the chamber 94, a pulse high voltage is applied between the electrodes 115a, 115b in the chamber 94 from a power source (not shown) of the amplifier 90. When discharge occurs between the electrodes 115a, 115b, the laser gas is excited, the seed light is amplified by the Fabry-Perot optical resonator configured of the rear mirror 92 and the output coupling mirror 98, and the amplified pulse laser light is output from the output coupling mirror 98.

The pulse laser light output from the output coupling mirror 98 enters the OPS 50. Operation of the OPS 50 and operation of deterioration estimation of the OPS 50 are similar to those of the first embodiment.

### 6.3 Effect

Effects of the fifth embodiment are similar to those of the first embodiment.

### 7. Sixth Embodiment

### 7.1 Configuration

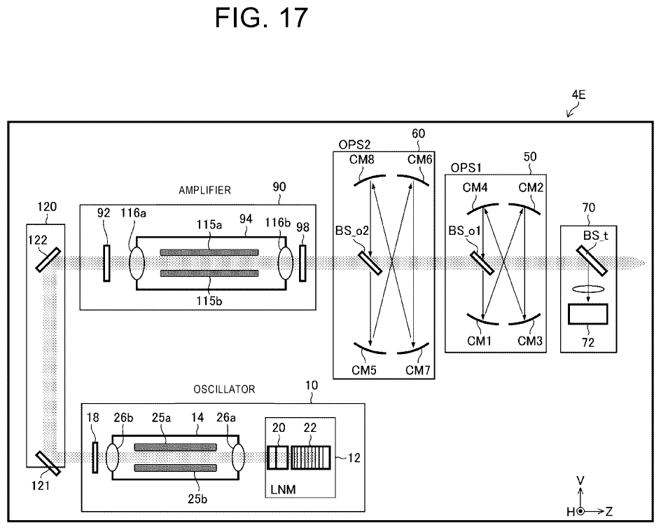

FIG. 17 schematically shows the configuration of a laser device 4E according to a sixth embodiment. The configuration of the laser device 4E will be described in terms of differences from the configuration of the laser device 4C according to the fourth embodiment shown in FIG. 12. The laser device 4E is different from the laser device 4C according to the fourth embodiment in that the amplifier 90 is included and the beam steering unit 120 is arranged between the oscillator 10 and the amplifier 90. Other configurations may be similar to those of the laser device 4C.

The configurations of the amplifier 90 and the beam steering unit 120 are similar to those of the fifth embodiment shown in FIG. 16.

### 7.2 Operation

Operation of the oscillator 10, the beam steering unit 120, and the amplifier 90 of the laser device 4E is similar to that of the fifth embodiment. The pulse laser light output from the output coupling mirror 98 of the amplifier 90 enters the OPS 60. Operation of the OPS 60 and the OPS 50 and operation of deterioration estimation of the OPS 60 and the OPS 50 are similar to those of the fourth embodiment.

### 7.3 Effect

Effects of the sixth embodiment are similar to those of the fourth embodiment.

### 8. Other Modification of Laser Device

In FIGS. 16 and 17, an example in which the oscillator 10 which is a gas laser is used as the oscillation stage laser for outputting the seed light to enter the amplifier 90 has been described. However, instead of the oscillator 10, for example, a solid-state laser system including a semiconductor laser and a wavelength conversion system may be employed. The wavelength conversion system may be configured using a nonlinear optical crystal. That is, the oscillation stage laser is not limited to a gas laser, and may be an ultraviolet solid-state laser that outputs pulse laser light having an ultraviolet wavelength. For example, the oscillation stage laser may be a solid-state laser that oscillates at a wavelength of about 193.4 nm, or an ultraviolet solid-state laser that outputs fourth harmonic light of a titanium-sapphire laser (wavelength of about 774 nm).

### 9. Electronic Device Manufacturing Method

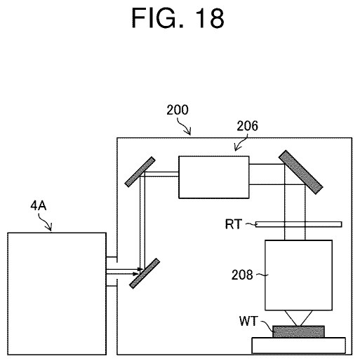

FIG. 18 schematically shows a configuration example of an exposure apparatus 200. The exposure apparatus 200 includes an illumination optical system 206 and a projection optical system 208. The laser device 4A generates laser light and outputs the laser light to the exposure apparatus 200. The illumination optical system 206 illuminates a reticle pattern of a reticle (not shown) arranged on a reticle stage RT with the laser light incident from the laser device 4A. The projection optical system 208 causes the laser light transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the laser light reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure. Not limited to the laser device 4A, any of the laser devices 4B to 4E like may be used.

### 10. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A deterioration estimation method of an optical pulse stretcher configured to extend a pulse width of pulse laser light, comprising:
acquiring a first temporal waveform, at a first measurement timing, of the pulse laser light having the pulse width extended by the optical pulse stretcher;
acquiring a second temporal waveform, at a second measurement timing after the first measurement timing, of the pulse laser light having the pulse width extended by the optical pulse stretcher; and
estimating a degree of deterioration of the optical pulse stretcher based on the first temporal waveform and the second temporal waveform.

2. The deterioration estimation method according to claim 1,
wherein a ratio R_12S of a maximum value P_1S at a first peak and a maximum value P_2S at a second peak of the first temporal waveform is calculated by Expression (a):
$$R\_ 12 S = P\_ 2 S / P\_ 1 S , \qquad ( a )$$
a ratio R_12E of a maximum value P_1E at a first peak and a maximum value P_2E at a second peak of the second temporal waveform is calculated by Expression (b):
$$R\_ 12 E = P\_ 2 E / P\_ 1 E , and \qquad ( b )$$
a deterioration degree D_1 indicating the degree of deterioration of the optical pulse stretcher is calculated by Expression (c):
$$D\_ 1 = R\_ 12 S - R\_ 12 E . \qquad ( c )$$

3. The deterioration estimation method according to claim 1,
wherein one of the first temporal waveform and the second temporal waveform is normalized so that maximum values thereof at a normalization peak selected from a plurality of peaks included in both of the first temporal waveform and the second temporal waveform are the same, and
a deterioration degree indicating the degree of deterioration of the optical pulse stretcher is calculated based on the normalized first temporal waveform and the second temporal waveform, or the first temporal waveform and the normalized second waveform.

4. The deterioration estimation method according to claim 3,
wherein a deterioration degree D_1 indicating the degree of deterioration of the optical pulse stretcher is calculated by Expression (d):
$$D\_ 1 = \vert 1 - P\_AE 1 / P\_AS 1 \vert , \qquad ( d )$$
where one peak other than the normalization peak is set as an evaluation peak, a maximum value at the evaluation peak of the normalized first temporal waveform or the first temporal waveform is P_AS1, and a maximum value at the evaluation peak of the second temporal waveform or the normalized second temporal waveform is P_AE1.

5. The deterioration estimation method according to claim 3,
wherein a deterioration degree D_1 indicating the degree of deterioration of the optical pulse stretcher is calculated by Expression (e):
$$D\_ 1 = 1 - S E / S\_ 2 S , \qquad ( e )$$
where an area of the first normalized temporal waveform or the first temporal waveform is S_2S, and an area of the second temporal waveform or the normalized second temporal waveform is S_2E.

6. The deterioration estimation method according to claim 1,
wherein a deterioration degree D_1 indicating the degree of deterioration of the optical pulse stretcher estimated based on the first temporal waveform and the second temporal waveform is output to a display device.

7. The deterioration estimation method according to claim 1,
wherein the optical pulse stretcher is estimated to be deteriorated when a deterioration degree D_1 indicating the degree of deterioration of the optical pulse stretcher estimated based on the first temporal waveform and the second temporal waveform is equal to or more than a first setting value.

8. The deterioration estimation method according to claim 1,
wherein a number of used pulses OPS1_dpls of the optical pulse stretcher with which a deterioration degree D_1 indicating the degree of deterioration of the optical pulse stretcher becomes a first setting value PV_1 is calculated by Expression (f):
$$OPS 1 \_dpls = PV\_ 1 / ( D\_ 1 / OPS 1 \_pls ) , \qquad ( f )$$
where the number of used pulses of the optical pulse stretcher at the second measurement timing is OPS1_dpls and the first setting value is PV_1.

9. The deterioration estimation method according to claim 1,
wherein a first optical pulse stretcher being the optical pulse stretcher includes a first beam splitter and a plurality of mirrors configuring a first delay optical path,
a laser device including the first optical pulse stretcher further includes a second pulse stretcher including a second beam splitter and a plurality of mirrors configuring a second delay optical path,
a delay optical path length of the second optical pulse stretcher is M times a delay optical path length of the first optical pulse stretcher, where M is an integer of 2 or more,
one of the first temporal waveform and the second temporal waveform is normalized based on maximum values at a normalization peak of the first temporal waveform and the second temporal waveform, the normalization peak being set to one of first to M-th peaks of each of the first temporal waveform and the second temporal waveform,
a deterioration degree D_1 indicating the degree of deterioration of the first optical pulse stretcher is calculated based on a maximum value at an evaluation peak of the normalized first temporal waveform or the first temporal waveform and a maximum value at the evaluation peak of the second temporal waveform or the normalized second temporal waveform, the evaluation peak being set to one of the first to M-th peaks other than the normalization peak, and
a deterioration degree D_2 indicating a degree of deterioration of the second optical pulse stretcher is calculated based on maximum values at any two peaks of the first to M-th peaks and a M+1-th peak of the normalized first temporal waveform or the first temporal waveform and the second temporal waveform or the normalized second temporal waveform.

10. The deterioration estimation method according to claim 9,
wherein a delay optical path length of the second optical pulse stretcher is twice a delay optical path length of the first optical pulse stretcher,
the deterioration degree D_1 is calculated by Expression (g):
$$D\_ 1 = \vert 1 - P\_ 2 E / P\_ 2 S \vert , \qquad ( g )$$
$$P\_ 3 S 1 is calculated by Expression \qquad ( h )$$
$$P\_ 3 S 1 = P\_ 2 S \times P\_ 2 S \times T\_BSo 1 \times T\_BSo 1 / P\_ 1 S / ( 1 - T\_BSo 1 ) / ( 1 - T\_BSo 1 ) \qquad ( h )$$
$$P\_ 3 E 1 is calculated by Expression ; \qquad ( i )$$
$$P\_ 3 E 1 = ( 1 - D\_ 1 ) \times ( 1 - D\_ 1 ) \times P\_ 3 S 1 , and \qquad ( i )$$
the deterioration degree D 2 is calculated by Expression (j):
$$D\_ 2 = 1 - ( P\_ 3 E - P\_ 3 E 1 ) / ( P\_ 3 S - P\_ 3 S 1 ) , \qquad ( j )$$
where P_1S, P_2S, and P_3S are maximum values at a first peak, a second peak, and a third peak of the normalized first temporal waveform or the first temporal waveform, respectively,
P_2E and P_3E are maximum values at a second peak and a third peak of the second temporal waveform or the normalized second temporal waveform, respectively,
a maximum value of light transmitted through the second beam splitter and circulated through the first delay optical path of the first optical pulse stretcher twice at a third peak of the normalized first temporal waveform or the first temporal waveform is P_3S1, and a maximum value of light transmitted through the second beam splitter and circulated through the first delay optical path of the first optical pulse stretcher twice at a third peak of the second temporal waveform or the normalized second temporal waveform is P_3E1;or a maximum value of light circulated through the first delay optical path of the first optical pulse stretcher twice and transmitted through the second beam splitter at a third peak of the normalized first temporal waveform or the first temporal waveform is P_3S1, and a maximum value of light circulated through the first delay optical path of the first optical pulse stretcher twice and transmitted through the second beam splitter at a third peak of the second temporal waveform or the normalized second temporal waveform is P_3E1,
a transmittance of the first beam splitter is T_BSo1, and
the normalization peak is a first peak, and the evaluation peak is a second peak.

11. A laser device comprising:
an oscillator configured to output pulse laser light;
an optical pulse stretcher configured to extend a pulse width of the pulse laser light;
a pulse waveform measurement instrument configured to measure a first temporal waveform, at a first measurement timing, of the pulse laser light having the pulse width extended by the optical pulse stretcher, and measure a second temporal waveform, at a second measurement timing after the first measurement timing, of the pulse laser light having the pulse width extended by the optical pulse stretcher; and
a processor configured to estimate a degree of deterioration of the optical pulse stretcher based on the first temporal waveform and the second temporal waveform.

12. The laser device according to claim 11,
wherein the processor:
calculates a ratio R_12S of a maximum value P_1S at a first peak and a maximum value P_2S at a second peak of the first temporal waveform by Expression (a):
$$R\_ 12 S = P\_ 2 S / P\_ 1 S , \qquad ( a )$$
calculates a ratio R_12E of a maximum value P_1E at a first peak and a maximum value P_2E at a second peak of the second temporal waveform by Expression (b):
$$R\_ 12 E = P\_ 2 E / P\_ 1 E , and$$
calculates a deterioration degree D_1 indicating the degree of deterioration of the optical pulse stretcher by Expression (c):
$$D\_ 1 = R\_ 12 S - R\_ 12 E . \qquad ( c )$$

13. The laser device according to claim 11,
wherein the processor:
normalizes one of the first temporal waveform and the second temporal waveform so that maximum values at a normalization peak selected from a plurality of peaks included in both of the first temporal waveform and the second temporal waveform are the same, and
calculates a deterioration degree indicating the degree of deterioration of the optical pulse stretcher based on the normalized first temporal waveform and the second temporal waveform or the first temporal waveform and the normalized second waveform.

14. The laser device according to claim 13,
wherein the processor calculates a deterioration degree D_1 indicating the degree of deterioration of the optical pulse stretcher by Expression (d):
$$D\_ 1 = \vert 1 - P\_AE 1 / P\_AS 1 \vert , \qquad ( d )$$
where one peak other than the normalization peak is set as an evaluation peak, a maximum value at the evaluation peak of the normalized first temporal waveform or the first temporal waveform is P_AS1, and a maximum value at the evaluation peak of the second temporal waveform or the normalized second temporal waveform is P_AE1.

15. The laser device according to claim 13,
wherein the processor calculates a deterioration degree D_1 indicating the degree of deterioration of the optical pulse stretcher by Expression (e):
$$D\_ 1 = 1 - S\_ 2 E / S\_ 2 S , \qquad ( e )$$
where an area of the first normalized temporal waveform or the first temporal waveform is S_2S, and an area of the second temporal waveform or the normalized second temporal waveform is S_2E.

16. The laser device according to claim 11,
wherein the processor calculates a number of used pulses OPS1_dpls of the optical pulse stretcher with which a deterioration degree D_1 indicating the degree of deterioration of the optical pulse stretcher becomes a first setting value PV_1 by Expression (f):
$$OPS 1 \_dpls = PV\_ 1 / ( D\_ 1 / OPS 1 \_pls ) , \qquad ( f )$$
where the number of used pulses of the optical pulse stretcher at the second measurement timing is OPS1_pls and the first setting value is PV_1.

17. The laser device according to claim 11,
further comprising an amplifier between the oscillator and the optical pulse stretcher.

18. The laser device according to claim 11,
further comprising a first optical pulse stretcher being the optical pulse stretcher and a second optical pulse stretcher,
wherein the first optical pulse stretcher includes a first beam splitter and a plurality of mirrors configuring a first delay optical path,
the second optical pulse stretcher includes a second beam splitter and a plurality of mirrors configuring a second delay optical path,
a delay optical path length of the second optical pulse stretcher is M times a delay optical path length of the first optical pulse stretcher, where M is an integer of 2 or more, and
the processor:
normalizes one of the first temporal waveform and the second temporal waveform based on maximum values at a normalization peak of the first temporal waveform and the second temporal, the normalization peak being set to one of first to M-th peaks of each of the first temporal waveform and the second temporal waveform,
calculates a deterioration degree D_1 indicating the degree of deterioration of the first optical pulse stretcher based on a maximum value at an evaluation peak of the normalized first temporal waveform or the first temporal waveform and a maximum value at the evaluation peak of the second temporal waveform or the normalized second temporal waveform, the evaluation peak being set to one of the first to M-th peaks other than the normalization peak, and
calculates a deterioration degree D_2 indicating a degree of deterioration of the second optical pulse stretcher based on maximum values at any two peaks of the first to M-th peak and a M+1-th peak of the normalized first temporal waveform or temporal waveform and the second temporal waveform or the normalized second temporal waveform.

19. The laser device according to claim 18,
wherein a delay optical path length of the second optical pulse stretcher is twice a delay optical path length of the first optical pulse stretcher,
the deterioration degree D_1 is calculated by Expression (g):
$$D\_ 1 = \vert 1 - P\_ 2 E / P\_ 2 S \vert , \qquad ( g )$$
$$P\_ 3 S 1 is calculated by Expression \qquad ( h )$$
$$P\_ 3 S 1 = P\_ 2 S \times P\_ 2 S \times T\_BSo 1 \times T\_BSo 1 / P\_ 1 S / ( 1 - T\_BSo 1 ) / ( 1 - T\_BSo 1 ) \qquad ( h )$$
$$P\_ 3 E 1 is calculated by Expression ; \qquad ( i )$$
$$P\_ 3 E 1 = ( 1 - D\_ 1 ) \times ( 1 - D\_ 1 ) \times P\_ 3 S 1 , and \qquad ( i )$$
the deterioration degree D_2 is calculated by Expression (j):
$$D\_ 2 = 1 - ( P\_ 3 E - P\_ 3 E 1 ) / ( P\_ 3 S - P\_ 3 S 1 ) , \qquad ( j )$$
where P_1S, P_2S, and P_3S are maximum values at a first peak, a second peak, and a third peak of the normalized first temporal waveform or the first temporal waveform, respectively,
P_2E and P_3E are maximum values at a second peak and a third peak of the second temporal waveform or the normalized second temporal waveform, respectively,
a maximum value of light transmitted through the second beam splitter and circulated through the first delay optical path of the first optical pulse stretcher twice at a third peak of the normalized first temporal waveform or the first temporal waveform is P_3S1, and a maximum value of light transmitted through the second beam splitter and circulated through the first delay optical path of the first optical pulse stretcher twice at a third peak of the second temporal waveform or the normalized second temporal waveform is P_3E1; or a maximum value of light circulated through the first delay optical path of the first optical pulse stretcher twice and transmitted through the second beam splitter at a third peak of the normalized first temporal waveform or the first temporal waveform is P_351, and a maximum value of light circulated through the first delay optical path of the first optical pulse stretcher twice and transmitted through the second beam splitter at a third peak of the second temporal waveform or the normalized second temporal waveform is P_3E1,
a transmittance of the first beam splitter is T_BSo1 and
the normalization peak is a first peak, and the evaluation peak is a second peak.

20. An electronic device manufacturing method, comprising:
generating laser light with a pulse width extended using a laser device;
outputting the laser light to an exposure apparatus; and
exposing a photosensitive substrate to the laser light in the exposure apparatus to manufacture an electronic device,
the laser device including:
an oscillator configured to output pulse laser light;
an optical pulse stretcher configured to extend the pulse width of the pulse laser light;
a pulse waveform measurement instrument configured to measure a first temporal waveform, at a first measurement timing, of the pulse laser light having the pulse width extended by the optical pulse stretcher, and measure a second temporal waveform, at a second measurement timing after the first measurement timing, of the pulse laser light having the pulse width extended by the optical pulse stretcher; and
a processor configured to estimate a degree of deterioration of the optical pulse stretcher based on the first temporal waveform and the second temporal waveform.
